(19) United States
(12) Patent Application Publication
(10) Pub. No.: US 2008/0075854 A1
(43) Pub. Date: Mar. 27, 2008

(54) Ex-situ vapor phase lubrication for magnetic recording media

(75) Inventors: Michael J. Stirniman, Fremont, CA (US); Xiaoding Ma, Fremont, CA (US); Jing Gui, Fremont, CA (US)

Correspondence Address: Seagate Technology;c/o DARBY & DARBY P.C., P.O. Box 770, Church Street Station, New York, NY, 10008-0770, US

(73) Assignee: SEAGATE TECHNOLOGY LLC, Scotts Valley, CA (US)

(21) Appl. No.: 11/527,466

(22) Filed: Sep. 27, 2006

(51) Int. Cl. C23C 16/00; B05D 3/06

(52) U.S. Cl. 427/248.1; 118/715; 427/558

(57) ABSTRACT

The embodiments of the invention relate to a lubrication system and a lubrication method, wherein the system contains pre-lubrication chamber for pre-treating a surface of a magnetic recording medium prior to deposition of a lubricant and a deposition chamber having an inlet for deposition of the lubricant on the surface of the magnetic recording medium in the deposition chamber, wherein the lubrication system is a stand alone lubrication system that is seperate from a magnetic layer deposition system for depositing a magnetic layer of the magnetic recording medium.

### FIELD OF THE INVENTION

The present invention relates to a recording media having an advanced lubricant for thin film storage medium, wherein the advanced lubricant is manufactured by ex-situ vapor phase lubrication.

### BACKGROUND

Magnetic discs with magnetizable media are used for data storage in most all computer systems. Current magnetic hard disc drives operate with the read-write heads only a few nanometers above the disc surface and at rather high speeds, typically a few meters per second. Because the read-write heads can contact the disc surface during operation, a layer of lubricant is coated on the disc surface to reduce wear and friction.

FIG. 1 shows a disk recording medium and a cross section of a disc showing the difference between longitudinal and perpendicular recording. Even though FIG. 1 shows one side of the non-magnetic disk, magnetic recording layers are sputter deposited on both sides of the non-magnetic aluminum substrate of FIG. 1. Also, even though FIG. 1 shows an aluminum substrate, other embodiments include a substrate made of glass, glass-ceramic, NiP/aluminum, metal alloys, plastic/polymer material, ceramic, glass-polymer, composite materials or other non-magnetic materials.

The lubricant film on hard discs provides protection to the underlying magnetic alloy by preventing wear of the carbon overcoat. In addition, it works in combination with the overcoat to provide protection against corrosion of the underlying magnetic alloy. The reliability of hard disks depends on the durability of the thin film media. As the spacing between head disk is being reduced aggressively to improve area storage density, media are facing many severe technical obstacles, such as weak durability, heavy lubricant pickup by the read-write head, unmanageable stiction/friction, etc. Lubrication plays unquestionably an important role in overcoming these technical difficulties.

Lubrication additive moieties, such as Bis(4-fluorophenoxy)-tetrakis(3-trifluoromethyl phenoxy) cyclotriphosphazene (X1-p) can improve tribological performance and corrosion resistance of thin film media. Generally, the lubricant is applied to the disc surface by vapor phase lubrication or by dipping the disc in a bath containing the lubricant.

Vapor phase lubrication of hard disks in a vacuum is disclosed in U.S. Pat. No. 6,183,831, which is incorporated herein by reference. An inline process for manufacturing magnetic recording media is schematically illustrated in FIG. 2. The disc substrates travel sequentially from the heater to a sub-seed layer deposition station and a sub-seed layer is formed on the disc substrates. Then, the disc substrates travel to a seed layer station for deposition of the seed layer, typically NiAI. Subsequent to the deposition of the sub-seed layer and the seed layer, the disc substrates are passed through the underlayer deposition station wherein the underlayer is deposited. The discs are then passed to the magnetic layer deposition station and then to the protective carbon overcoat deposition station. Finally, the discs are passed through a lubricant film deposition station.

Sputtering leads to some particulates formation on the post sputter disks. These particulates need to be removed to ensure that they do not lead to the scratching between the head and substrate. Thus, a lube is preferably applied to the substrate surface as one of the top layers on the substrate.

The embodiments of the invention include sequential carbon deposition in a first process chamber, then vacuum deposition of lubricant in separate chamber (according to the method described in U.S. Pat. No. 6,183,831, incorporated herein by reference), followed by UV cure, in vacuum, in a sequential chamber, followed by unload of the discs from the in line deposition system.

Subsequently, the disk is prepared and tested for quality through a three-stage process. First, a burnishing head passes over the surface, removing any bumps (asperities as the technical term goes). The glide head then goes over the disk, checking for remaining bumps, if any. Finally the certifying head checks the surface for manufacturing defects and also measures the magnetic recording ability of the substrate.

In the prior art in-line process, hard disks are first coated with all the magnetic layers and a carbon overcoat, and then transported while in vacuum to a vapor lubrication deposition system and coated with a thin layer of lubricant without exposure to the atmosphere. Since the continuous vacuum process requires that the vapor lubrication system is necessarily connected to the magnetic layer deposition system, any operational problem in vapor lubrication system will result in shutdown of the magnetic sputter system as well, limiting efficiency and throughput. In addition, the varied configurations of sputter deposition equipment require multiple designs of vapor deposition equipment. In contrast, because the standard dip lubrication equipment is separate from the sputter system, only a single design of dip lubrication equipment is required and the lubrication process is not the limiting factor for the overall hard disk manufacturing efficiency. A vapor lubrication process that is separate from the sputter system is highly desirable.

### SUMMARY OF THE INVENTION

The embodiments of the invention relate to a lubrication system comprising a pre-lubrication chamber for pre-treating a surface of a magnetic recording medium prior to deposition of a lubricant and a deposition chamber comprising an inlet for deposition of the lubricant on the surface of the magnetic recording medium in the deposition chamber, wherein the lubrication system is a stand alone lubrication system that is separate from a magnetic layer deposition system for depositing a magnetic layer of the magnetic recording medium. Preferably, there could be a source chamber, wherein the source chamber communicates with the deposition chamber. Preferably, the deposition chamber further comprises a UV or xenon excimer lamp, wherein the deposition chamber has an ability to perform both a vapor deposition of the lubricant and an UV exposure of the lubricant. Preferably, the xenon excimer lamp operates under a vacuum and wherein the xenon excimer lamp produces more than 25% of the power at a wavelength of 185 nm or less. Preferably, the system does not include purging with a coolant to cool the xenon excimer lamp. Preferably, the deposition chamber is under a vacuum.

Another embodiment relates to a method comprising depositing a lubricant on a magnetic recording medium in a lubrication system comprising pre-treating a surface of the magnetic recording medium prior to deposition of a lubricant to form a pre-treated surface in a pre-lubrication chamber and depositing a lubricant on the pre-treated surface in a deposition chamber comprising an inlet for deposition of the lubricant on the pre-treated surface, wherein the lubrication system is a stand alone lubrication system that is separate from a magnetic layer deposition system for depositing a magnetic layer of the magnetic recording medium. The method could further comprise providing the lubricant from a source chamber to the deposition chamber, wherein the source chamber communicates with the deposition chamber. The method could further comprise evacuating the deposition chamber and the source chamber with a vacuum source to a pressure below atmospheric. The method could further comprise heating the lubricant in the source chamber so that the pressure in the source chamber is greater than the pressure in the deposition chamber. Preferably, the depositing the lubricant on the pre-treated surface of the magnetic recording medium in the deposition chamber comprises exposing the magnetic recording medium in the deposition chamber to the lubricant for a time sufficient to deposit the lubricant topcoat on the surface of the magnetic recording medium. Preferably, the depositing the lubricant on the magnetic medium in the deposition chamber is at a pressure no greater than about 100 Torr. The method could further compre heating the lubricant in the source chamber and comprising controlling the flow of the lubricant between the source chamber and the deposition chamber with a controller valve. Preferably, the deposition chamber further comprises a UV or xenon excimer lamp, and performing both a vapor deposition of the lubricant on the pre-treated surface of the magnetic recording medium and an UV exposure of the lubricant. Preferably, the lubricant comprises at least one perfluoropolyether compound and a phosphazene derivative. Preferably, the lubricant is formed on a surface of a data/information storage and retrieval medium. Preferably, the data/information storage and retrieval medium is a disk-shaped magnetic or magneto-optical (MO) recording medium. Preferably, the medium comprises a layer stack formed on a substrate surface, the layer stack including an uppermost, carbon (C)-containing protective overcoat layer, and the lubricant thin film is in the form of a topcoat layer in overlying contact with the carbon C)-containing protective overcoat layer. Preferably, the phosphazene derivative is bis (4-fluorophenoxy)-tetrakis (3-trifluoromethyl phenoxy) cyclo-triphosphazene. The method could further comprise varying the wavelength of maximum absorption of UV radiation by the lubricant by varying the temperature of the lubricant during the UV exposure.

Additional advantages of this invention will become readily apparent to those skilled in this art from the following detailed description, wherein only the preferred embodiments of this invention is shown and described, simply by way of illustration of the best mode contemplated for carrying out this invention. As will be realized, this invention a property of other and different embodiments, and its details are capable of modifications in various obvious respects, all without departing from this invention. Accordingly, the drawings and description are to be regarded as illustrative in nature and not as restrictive.

### BRIEF DESCRIPTION OF THE DRAWINGS

The present invention will be better understood by reference to the Detailed Description of the Invention when taken together with the attached drawings, wherein:

FIG. 1 shows a magnetic recording medium.

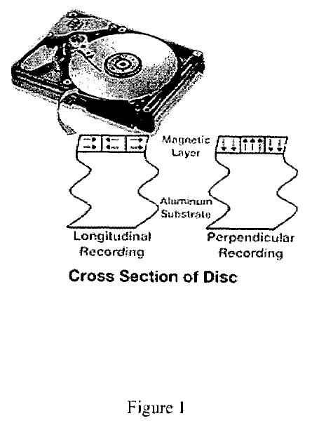

FIG. 2 shown an inline process for manufacturing magnetic recording media.

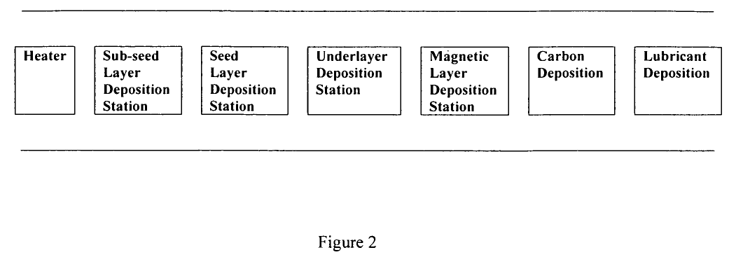

FIG. 3 shows a standalone vapor lubricant process system.

FIG. 4 shows a comparison of ex-situ vapor lubricant with and without pre-etching with conventional dip-lubricant.

FIG. 5 shows a diagram of a typical Xenon excimer UV lamp (from Xeradex lamp marketing brochure, Osram GmbH).

### DETAILED DESCRIPTION OF THE INVENTION

The invention is directed to a method of coating a substrate, particularly recording media (recording discs), with a lubricant, which is also referred in the specification to as a “lube.” Lubricants typically are liquid perfluoropolyethers and contain molecular weight components that range from several hundred Daltons to several thousand Daltons.

The embodiments of the invention could include an off line vacuum system that is separate from the metal and carbon in-line system, and which could preferably only do sequential vacuum deposition of lubricant followed by vacuum UV cure, followed by vent and unload.

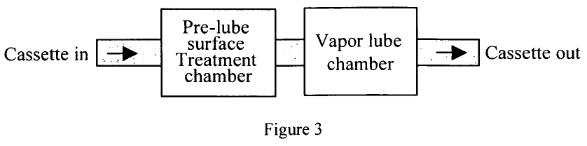

For example, the embodiments of the invention relate to a stand-alone vapor lubrication system that is separate from the sputter system. Hard disks are first coated with all the metal layers and a carbon overcoat, and then come out of the sputter machine vacuum as in the conventional sputter process. The post-sputter disks are loaded into a stand-alone vapor lubrication system to be coated with a thin layer of lubricant (referred as ex-situ vapor lubrication). The stand-alone vapor lubrication system can consist of a pre-lubricant surface treatment chamber (for example sputter etching or UV/ozone cleaning), a vapor lubrication chamber, and a post-lubrication process chamber (for example UV cure), in any combination. An example of one configuration is shown in FIG. 3.

Ultraviolet (UV) light has been widely used in the disk drive industry to increase the chemical interactions between media lubricants and media carbon overcoats. These increased interactions are generally described by the widely used but chemically imprecise industry term “bonded lubricant.” By this terminology, the bonded lubricant fraction refers to the percentage of the total lubricant film that remains on the carbon overcoat after some standardized solvent wash procedure. After the UV exposure of a lubricant film, the fractional amount of the total lubricant that is bonded is typically seen to increase, sometimes dramatically. The amount of increase depends on a number of factors, including the UV exposure time, the UV power density at the disk surface, the UV wavelength, the lubricant type and initial thickness, and the exposure environmental conditions such as temperature and oxygen partial pressure. The oxygen partial pressure is considered to be a particularly relevant parameter, due to the ability of UV photons with sufficiently high energy to break the O₂ bond and create the corrosive gas ozone during the cure process.

UV curing could be done by using mercury discharge lamps. The UV process depends strongly on the UV photon energy. In the case of the mercury discharge UV lamp, it generates only a small fraction (<15%) of its total output at the useful wavelength of 185 nm with a photon energy of 6.7 eV, with the main fraction of the power being consumed at the less useful 254 nm wavelength with a photon energy of 4.9 eV.

Xenon excimer UV lamp produces UV light at the useful wavelength of 172 nm with a photon energy of 7.2 eV. At this high energy, the 172 nm UV photon has energy high enough to break many chemical bonds. While not being limited by description on how the Xenon excimer UV lamp works, it is believed that excitation of Xenon atoms (Xe) by electrons form excited Xenon atoms (Xe*). The excited Xe* atoms react in a three body collision to form an Xe₂* excimer complex which radiates at 172 nm. This excimer system can be pumped at very high power densities (>1 MW/cm²) and is not subjected to self-absorption because the excimer has no stable ground state.

Preferably, the vapor deposition on the media and the subsequent exposure of the media to the excimer UV lamp could be done in the same chamber, and furthermore preferably without moving the media between the steps of the vapor deposition and UV exposure from the excimer UV lamp.

In the embodiments of the invention, the same chamber for both vapor deposition and UV exposure of the lubricant could be as follows. Embodiments of the present invention comprise suspending a magnetic recording medium in a deposition chamber and providing a lubricant in a source chamber as in U.S. Pat. Nos. 6,214,410, and 6,183,831, which are incorporated herein by reference. The deposition and source chambers can be constructed of any material which will function at sub-atmospheric pressures and does not interfere with the deposition process, and does not adversely affect the desired properties of the resulting product, e.g. glass, ceramic or metal. A vacuum source could be employed to evacuate the deposition and source chambers to a pressure below atmospheric pressure, e.g. a pressure less than about 760 Torr. The temperature of the lubricant in the source chamber, i.e., the chamber which is the source of the lubricant supplied to the deposition chamber, could be then elevated above the temperature of the magnetic recording medium in the deposition chamber, which elevated temperature causes vaporized lubricant in the source chamber to flow from the source chamber to the deposition chamber and condense on a surface of the magnetic recording medium to form a lubricant topcoat. After sufficient time has elapsed to deposit a topcoat having a substantially uniform thickness substantially completely covering the surface of the recording medium, the deposition chamber can be vented to the atmosphere, or vented with a desired gas. The magnetic recording medium could then be UV treated in the same deposition chamber, and finally removed.

In accordance with embodiments of the present invention, the deposition and source chambers can be evacuated substantially concurrently to substantially the same relative pressure of about 100 Torr to about 10⁻¹⁰ Torr. After evacuating the deposition and source chambers to the desired pressure, the source chamber can be isolated from the deposition chamber and the vacuum source employing a conventional valve. Subsequent heating of the lubricant in the source chamber causes the pressure in the source chamber to increase relative to the pressure in the deposition chamber. By then opening the valve, lubricant vapor in the source chamber will flow from the source chamber to the deposition chamber. Since the deposition chamber is at a lower temperature and pressure, the heated lubricant from the source chamber deposits on the magnetic recording medium within the deposition chamber. The valve is opened for a period of time sufficient to deposit the lubricant topcoat at a desired uniform thickness. Thereafter, the valve is closed, the deposition chamber vented, the recording medium removed and the method steps repeated.

In an embodiment of the present invention, the vacuum source can be isolated from the apparatus employing another valve positioned between the vacuum source and the apparatus. By closing such a valve, the vacuum source can be isolated from the deposition chamber prior to exposing the magnetic recording medium to lubricant vapor in the deposition chamber. Practical considerations may require application of the vacuum to the deposition chamber during which the lubricant is heated in the source chamber and to ensure an adequate pressure differential between the two chambers. An embodiment of the present invention includes the use of a valve between the deposition chamber and the vacuum source.

According to the present invention, it is understood that the deposition of a lubricant topcoat on a surface of a magnetic recording medium at sub-atmospheric pressure yields improved control over the deposited topcoat layer. The amount, quality and molecular weight of the lubricant vapor which flows from the source chamber to the deposition chamber is dependent upon the relative pressure difference and the relative temperature difference between the two chambers.

It is particularly effective to reduce the pressure in the deposition chamber to within the range of about 10 Torr to about 10⁻¹⁰ Torr, e.g., within the range of about 10 ⁻³ Torr to about 10⁻⁹ Torr. Further, by elevating the temperature of the lubricant in the source chamber, the pressure of the source chamber is increased relative to the deposition chamber. Embodiments of the present invention include elevating the temperature of the lubricant in the source chamber to greater than about 35° C. but less than about 300° C., e.g., a temperature within the range of about 120° C. to about 220° C. By elevating the temperature of the lubricant in the source chamber, the pressure in the source chamber is also elevated. Embodiments of the present invention include evacuating the source chamber to a pressure of about 700 Torr to about 10⁻⁵ Torr, e.g., about 100 Torr to about 0.01 Torr

Irradiation of media could be achieved through the use of an irradiation apparatus comprising the deposition chamber. In such an irradiation process, discs could placed on a saddle and lifted individually into a space between two ultraviolet lamps in a dedicated process chamber.

To be of practical use, the UV cure process requires vacuum compatible UV lamps that output high enough power at high enough photon energy to effect curing in times on the order of 10 seconds or less. Excimer UV lamps output a single high-energy wavelength (e.g., 172 nm) at power densities of about 50 mW/cm², with an energy conversion efficiency of around 40%. This compares to the typical total power output of 20-30 mW/cm² from a mercury discharge lamp, only 3-5 mW/cm² or less of which is at the useful wavelength of 185 nm, and which operate at much lower conversion efficiencies. The excimer lamp can also be manufactured with vacuum compatible components, which is difficult to achieve with mercury discharge lamps. Excimer lamps use environmentally benign xenon as the working gas, eliminating the hazards associated with mercury. Finally, excimer lamps run considerably cooler than mercury discharge lamps, and no external cooling is required.

Operating the excimer lamp in vacuum simultaneously eliminates both the need for nitrogen purge and the generation of ozone during the process. If on the other hand ozone is in fact found to be of benefit, it could be incorporated into the process in a controlled manner by back filling the deposition chamber with oxygen. The UV process in conjunction with vapor deposition of lubricant eliminates the need for external UV curing tools and their associated floor space and handling steps. The vacuum process using the excimer lamp is additionally more efficient than the UV process using the mercury discharge lamp as it eliminates the attenuation of the UV power by ambient nitrogen. Unlike mercury discharge lamps, which require long warm-up times and need to be run continuously to maintain a steady output, excimer lamps require less than 1 second warm up time to reach full power, and thus can be turned on and off as part of the process.

The lubricant moieties include polyfluoroether compositions that may be terminally functionalized with polar groups, such as hydroxyl, carboxy, or amino. The polar groups provide a means of better attaching or sticking the lubricant onto the surface of the recording media. These fluorinated oils are commercially available under such trade names as Fomblin Z®, Fomblin Z-Dol ®, Fomblin Ztetraol®, Fomblin Am2001®, Fomblin Z-DISOC® (Montedison); Demnum® (Daikin) and Krytox® (Dupont).

The chemical structures of some of the Fomblin lubricants are shown below.

X—CF₂—[(OCF₂—CF₂)ₘ—(OCF₂)ₙ]—OCF₂—X

### Fomblin Z: Non-reactive end groups

X═F

### Fomblin Zdol: Reactive end groups

X═CH₂—OH

### Fomblin AM2001: Reactive end groups

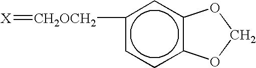

### Fomblin Ztetraol: Reactive end groups

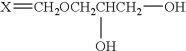

X1p is the most widely used lubricant additive for thin film storage medium. X-1p is available from the Dow Chemical Company. It has the formula:

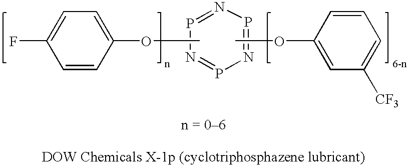

The most remarkable benefit from X1p application is the significant improvement of durability of storage medium. However, the durability benefit of X1p could be accompanied by potential problems, such as X1p phrase separation, head smear and lubricant pickup due to the limited miscibility of X1p in PFPE lubricant. Chemically linking lubricant molecules, such as Zdol, to the cyclotriphosphazene moiety could eliminate the low miscibility problems between lubricant and X1p. However, UV light could activate X1p very effectively. The fluorophenol and trifluoromethylphenol substituents on the cyclotriphosphazene ring in X1p could be excited readily by UV exposure. A sequence of photochemical reactions could be triggered, involving shedding of the fluorophenol and trifluoromethylphenol substituents from the cyclotriphosphazene ring.

The additive moieties that could be added to the lubricant moieties in this invention include X1-p and its derivatives. Also, adding a UV curable end group to the main lubricant further dramatically decreases the time to saturation. For example, the following UV curable compounds work with Z-DOL: acrylate, methacrylate, styrene, a-methyl styrene and vinyl ester.

The UV curable end group may be added to Z-DOL by reacting it with Acrylic chloride in the following reaction:

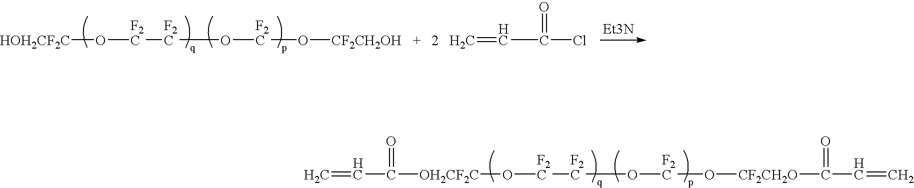

In addition to an acrylate functional group, other polymerizable functional groups including methacrylate, vinyl ester and 4-vinylbenzylate can also serve the purpose of providing a UV-curable functional end group. Those of ordinary skill may vary the particular ultraviolet wavelengths and UV-curable end groups according to the specific application which includes lubricant other than Z-DOL without varying from the scope of the invention as defined in the appended claims.

The thickness of the lubricant coating should be at least 0.5 nm, preferably at least 1 nm, and more preferably at least 1.2 nm and will generally be below 3 nm, preferably in the range from 1 nm to 3 nm. Molecular weight components of particular interest that provide higher film thickness range from 1 kD to 10 kD, preferably from 2 kD to 8 kD.

One way of describing a distribution of molecular components of a polymer, i.e., polydispersity, is to compare the weight average molecular weight defined as

M_{w}=ΣmᵢMᵢ/Σmᵢ

where mᵢ is the total mass of molecular component in the polymer having a molecular weight Mᵢ, with the number average molecular weight defined as

Mₙ=ΣNᵢMᵢ/ΣNᵢ

where Nᵢ is the total number of each molecular component in the polymer having a molecular weight Mᵢ. The weight average molecular weight (Mₙ) of a polymer will always be greater than the number average molecular weight (Mₙ), because the later counts the contribution of molecules in each class Mᵢ and the former weighs their contribution in terms of their mass. Thus, those molecular components having a high molecular weight contribute more to the average when mass rather than number is used as the weighing factor.

For all polydisperse polymers the ratio M_{w}/Mₙ is always greater than one, and the amount by which this ratio deviates from one is a measure of the polydispersity of the polymer. The larger the M_{w}/Mₙ ratio the greater the breadth of the molecular weight distribution of the polymer.

The molecular weight distribution of the vapor phase can be sampled by condensation of the vapor onto a suitable surface, followed by analysis of the condensate in a calibrated size exclusion chromatography system.

It is desirable that the lubricant has a relatively narrow molecular weight distribution of molecular components. In practice, the narrower the distribution the easier it will be to maintain a steady-state concentration of one or more components in the vapor. For example, if the highest and lowest molecular weight components in the polymer have very similar molecular weights, their vapor pressures will also be very similar. On the other hand, if the molecular weights (vapor pressures) are dramatically different heating of the lubricant will require much greater temperature and process control for a steady state concentration to be maintained. The lubricant used in the invention should have an M_{w}/Mₙ ratio between 1 and 1.6, preferably between 1 and 1.3, more preferably between 1 and 1.2.

The invention can be practiced with any commercial lubricant with a relatively large or small polydispersity, or with a lubricant that has been pre-fractionated to obtain a lubricant with a relatively small polydispersity. The preferred embodiment of the invention does not involve pre-fractionation of the lubricant. However, pre-fractionated lubricants may be used to provide relatively narrow molecular weight lubricant. If a pre-fractionated lubricant is used in the invention, distillation, chromatography, extraction, or other techniques that allow separation can obtain the pre-fractionated lubricant by molecular weight.

### EXAMPLES

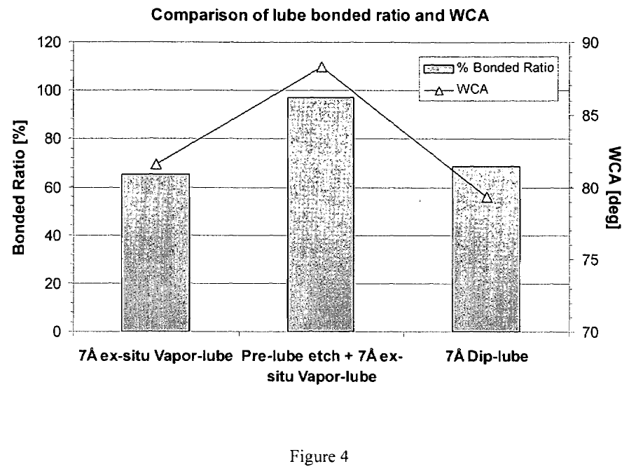

FIG. 4 shows the lubricant bonded ratio and WCA data for 7 Å Ztetraol coated by a conventional dip-lubrication process, the ex-situ vapor lubrication process, and the ex-situ vapor lubrication process with pre-lubrication Ar ion surface treatment. FIG. 4 shows that the ex-situ vapor-lubricated cell has very similar bonded ratio and WCA values as the conventional dip-lubricated cell. The pre-lubrication surface ion etch enhances and lubricant bonding and reduces the surface energy.

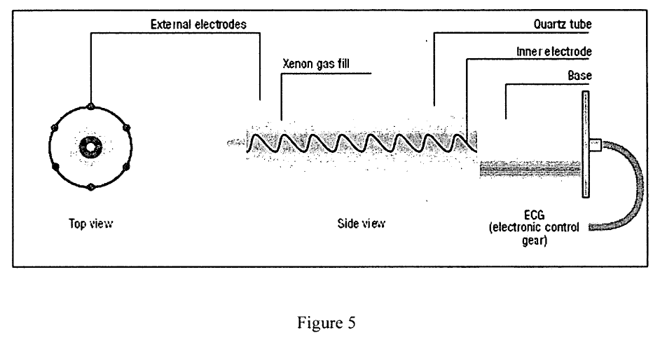

Optionally, the vapor-lubricated cell could be fitted with an excimer UV lamp (Osram GmbH, Munich Germany) shown in FIG. 5 to further increase bonded ratio and WCA of the disks having ex-situ vapor-lube and pre-lube etch and ex-situ vapor lube.

In this application, the word “containing” means that a material comprises the elements or compounds before the word “containing” but the material could still include other elements and compounds. This application discloses several numerical ranges in the text and figures. The numerical ranges disclosed inherently support any range or value within the disclosed numerical ranges even though a precise range limitation is not stated verbatim in the specification because this invention can be practiced throughout the disclosed numerical ranges.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles

What is claimed is:

1. A lubrication system comprising a pre-lubrication chamber for pre-treating a surface of a magnetic recording medium prior to deposition of a lubricant and a deposition chamber comprising an inlet for deposition of the lubricant on the surface of the magnetic recording medium in the deposition chamber, wherein the lubrication system is a stand alone lubrication system that is separate from a magnetic layer deposition system for depositing a magnetic layer of the magnetic recording medium.

2. The system of claim 1, further comprising a source chamber, wherein the source chamber communicates with the deposition chamber.

3. The system of claim 1, wherein the deposition chamber further comprises a UV or xenon excimer lamp, wherein the deposition chamber has an ability to perform both a vapor deposition of the lubricant and an UV exposure of the lubricant.

4. The system of claim 1, wherein the xenon excimer lamp operates under a vacuum and wherein the xenon excimer lamp produces more than 25% of the power at a wavelength of 185 nm or less.

5. The system of claim 1, wherein the system does not include purging with a coolant to cool the xenon excimer lamp.

6. The system of claim 1, wherein the deposition chamber is under a vacuum. and features disclosed herein. Finally, the entire disclosure of the patents and publications referred in this application are hereby incorporated herein by reference.

7. A method comprising depositing a lubricant on a magnetic recording medium in a lubrication system comprising pre-treating a surface of the magnetic recording medium prior to deposition of a lubricant to form a pre-treated surface in a pre-lubrication chamber and depositing a lubricant on the pre-treated surface in a deposition chamber comprising an inlet for deposition of the lubricant on the pre-treated surface, wherein the lubrication system is a stand alone lubrication system that is separate from a magnetic layer deposition system for depositing a magnetic layer of the magnetic recording medium.

8. The method of claim 7, further comprising providing the lubricant from a source chamber to the deposition chamber, wherein the source chamber communicates with the deposition chamber.

9. The method of claim 8, further comprising evacuating the deposition chamber and the source chamber with a vacuum source to a pressure below atmospheric.

10. The method of claim 9, further comprising heating the lubricant in the source chamber so that the pressure in the source chamber is greater than the pressure in the deposition chamber.

11. The method of claim 10, wherein the depositing the lubricant on the pre-treated surface of the magnetic recording medium in the deposition chamber comprises exposing the magnetic recording medium in the deposition chamber to the lubricant for a time sufficient to deposit the lubricant topcoat on the surface of the magnetic recording medium.

12. The method of claim 1, wherein the depositing the lubricant on the magnetic medium in the deposition chamber is at a pressure no greater than about 100 Torr.

13. The method of claim 12, further comprising heating the lubricant in the source chamber and comprising controlling the flow of the lubricant between the source chamber and the deposition chamber with a controller valve.

14. The method of claim 7, wherein the deposition chamber further comprises a UV or xenon excimer lamp, and performing both a vapor deposition of the lubricant on the pre-treated surface of the magnetic recording medium and an UV exposure of the lubricant.

15. The method of claim 7, wherein the lubricant comprises at least one perfluoropolyether compound and a phosphazene derivative.

16. The method as in claim 7, wherein the lubricant is formed on a surface of a data/information storage and retrieval medium.

17. The method as in claim 16, wherein the data/information storage and retrieval medium is a disk-shaped magnetic or magneto-optical (MO) recording medium.

18. The method as in claim 17, wherein the medium comprises a layer stack formed on a substrate surface, the layer stack including an uppermost, carbon (C)-containing protective overcoat layer, and the lubricant thin film is in the form of a topcoat layer in overlying contact with the carbon (C)-containing protective overcoat layer.

19. The method as in claim 15 wherein the phosphazene derivative is bis (4-fluorophenoxy)-tetrakis(3-trifluoromethyl phenoxy) cyclo-triphosphazene.

20. The method as in claim 14, further comprising varying the wavelength of maximum absorption of UV radiation by the lubricant by varying the temperature of the lubricant during UV exposure.
